(19) United States
(12) Patent Application Publication
(10) Pub. No.: US 2025/0336638 A1
(43) Pub. Date: Oct. 30, 2025

(54) WIRELESS CHAMBER SENSOR

(71) Applicant: Applied Materials, Inc., Santa Clara, CA (US)

(72) Inventors: CHUANG-CHIA LIN, San Ramon, CA (US); QIANYI XIE, Sunnyvale, CA (US)

(21) Appl. No.: 18/648,153

(22) Filed: Apr. 26, 2024

(51) Int. Cl. H01J 37/244; H01J 37/32; H02J 50/20

(52) U.S. Cl. CPC H01J 37/244; H01J 37/3211; H01J 2237/24578; H01J 2237/24585; H02J 50/20

(57) ABSTRACT

Embodiments disclosed herein relate to an apparatus that includes a housing with a cavity, and a cover with a first surface and a second surface. In an embodiment, the cover is coupled to the housing with the second surface facing the housing. In an embodiment, a sensor is on the first surface of the cover, and a battery is electrically coupled to the sensor. In an embodiment, the battery is within the cavity.

### BACKGROUND

### 1) Field

Embodiments of the present disclosure pertain to the field of wireless chamber sensors.

### 2) Description of Related Art

Processing chambers, such as a vacuum chambers, are used extensively in semiconductor manufacturing process flows. Vacuum chambers may be suitable for supporting plasmas in order to process substrates within the chamber. For example, semiconductor wafers (e.g., silicon wafers) can be processed in a plasma environment. The plasma may be used in order to deposit layers on the substrate, etch portions of the substrate, treat surfaces of the substrate, and/or the like.

In order to maintain high process uniformity and/or control of processing conditions, it is beneficial to closely monitor the chamber environment. For example, the deposition of material on interior surfaces of the chamber may negatively impact process uniformity or yield. For example, particles from layers deposited on chamber sidewalls can flake off and deposit on the substrate. This can result in yield decreases in some instances. Accordingly, process monitoring sensors have been deployed within the chamber to monitor chamber conditions.

### SUMMARY

Embodiments disclosed herein relate to an apparatus that includes a housing with a cavity, and a cover with a first surface and a second surface. In an embodiment, the cover is coupled to the housing with the second surface facing the housing. In an embodiment, a sensor is on the first surface of the cover, and a battery is electrically coupled to the sensor. In an embodiment, the battery is within the cavity.

Embodiments disclosed herein relate to an apparatus that includes a chamber, and a sensor system within the chamber. In an embodiment, the sensor system includes a housing with a cavity, where the housing is coupled to an interior surface of the chamber. The sensor system may further include a cover with a first surface and a second surface, where the cover is coupled to the housing with the second surface facing the housing. In an embodiment, a sensor is on the first surface of the cover, where at least a portion of the sensor is exposed to an internal environment of the chamber. The sensor system may also include an antenna.

Embodiments disclosed herein relate to an apparatus that includes a housing, where the housing includes cavity. In an embodiment, the housing is a ceramic material. In an embodiment, a cover is coupled to the housing, where the cover covers the cavity in the housing. In an embodiment, the apparatus further includes a battery within the cavity, and an antenna electrically coupled to the battery. A first sensor and a second sensor may be on the cover facing away from the housing, where the second sensor is covered by a layer.

### BRIEF DESCRIPTION OF THE DRAWINGS

FIG. 1 is an exploded view of a wireless sensor system that enables wireless charging and/or wireless data transfer from within a chamber, in accordance with an embodiment.

FIG. 2A is a plan view illustration of a top surface of a cover of the wireless sensor system, in accordance with an embodiment.

FIG. 2B is a plan view illustration of a bottom surface of a cover of the wireless sensor system, in accordance with an embodiment.

FIG. 3A is a plan view illustration of a housing of the wireless sensor system, in accordance with an embodiment.

FIG. 3B is a plan view illustration of a housing of the wireless sensor system with a board and components within a cavity, in accordance with an embodiment.

FIG. 4A is a cross-sectional illustration of a wireless sensor system with components on a board in the cavity and an antenna along sidewalls of the cavity, in accordance with an embodiment.

FIG. 4B is a cross-sectional illustration of a wireless sensor system with components on a backside of the cover and within the cavity, in accordance with an embodiment.

FIG. 4C is a cross-sectional illustration of a wireless sensor system with components on a board in the cavity, in accordance with an embodiment.

FIG. 4D is a cross-sectional illustration of a wireless sensor system with components on a backside of the cover and within the cavity, in accordance with an embodiment.

FIG. 5A is a cross-sectional illustration of a plasma chamber with one or more wireless sensors, in accordance with an embodiment.

FIG. 5B is a cross-sectional illustration of a plasma chamber with one or more wireless sensors that are powered by a remote antenna, in accordance with an embodiment.

FIG. 6 is a process flow diagram of a process for monitoring an interior chamber condition with a sensor system that is wirelessly charged through RF power delivery, in accordance with an embodiment.

FIG. 7 illustrates a block diagram of an exemplary computer system of a processing tool, in accordance with an embodiment of the present disclosure.

### DETAILED DESCRIPTION

Wireless chamber sensors with batteries that are charged through RF power delivered to the chamber are described herein in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, chamber monitoring is important in order to maintain high performance processing within the chamber. For example, deposition of layers on interior chamber surfaces can result in non-uniform processing and/or provide a source of defects that can deposit onto the substrate within the chamber. Some previous solutions include providing a coupon within the chamber. After the one or more iterations of a processing operation within the chamber, the chamber is vented in order to remove the coupon. The coupon is then analyzed in order to track changes to the interior chamber surface. However, this requires frequent venting of the chamber, which takes the chamber offline for long durations. Additionally, coupons only allow for a snapshot of the end of the process.

Some active sensors have been proposed to monitor the chamber condition. However, the inclusion of such sensors require batteries or other energy storage in order to power the sensors. Since the sensors are battery powered, the use of such sensors have a limited duration. Ultimately, the chamber still needs to be vented in order to retrieve the sensor and recharge the battery.

Accordingly, embodiments disclosed herein include a sensor system that provides persistent charging through wireless power delivery. In some embodiments, the sensor system may comprise a housing with a cavity. The cavity is sealed by a cover in order to provide a region protected from the plasma environment. Sensitive components (e.g., a battery, a memory, a processor, etc.) can be provided in the sealed cavity. Sensors can be provided on the surface of the cover facing the chamber environment in order to detect one or more chamber conditions. In an embodiment, the sensor system may further comprise an antenna that is configured to receive RF power that is provided into the chamber to initiate and/or sustain the plasma. The antenna is electrically coupled to the battery. This allows for RF power to charge the battery during operation of the chamber. Accordingly, the battery is repeatedly charged, and the sensor can be used for longer durations.

The use of such a wirelessly rechargeable sensor system is advantageous for several reasons. In one embodiment, the rechargeable power storage solution allows for the sensor system to operate for any duration. For example, the sensor system may operate through an entire duration between planned maintenance (PM) events. As such, there is no additional downtime for the chamber to accommodate the sensor system. This increases uptime and improves throughput. The wirelessly rechargeable nature of the sensor systems described herein also allow for the inclusion of multiple sensor systems within the chamber, and/or the ability to mount the sensor system to many different surfaces within the chamber. For example, the sensor system may be provided on a chamber wall, a chamber liner, a process kit, a chamber lid, and/or the like. The housing and cover configuration of sensor systems described herein may also benefit the sensor system's ability to withstand harsh plasma environments since sensitive components are protected. Another advantage of embodiments disclosed herein is that the sensor system allows for real time (or near real time) monitoring of changes within the chamber. For example, a wireless data transmission module within the sensor system may transmit data to an external controller or other device in some embodiment.

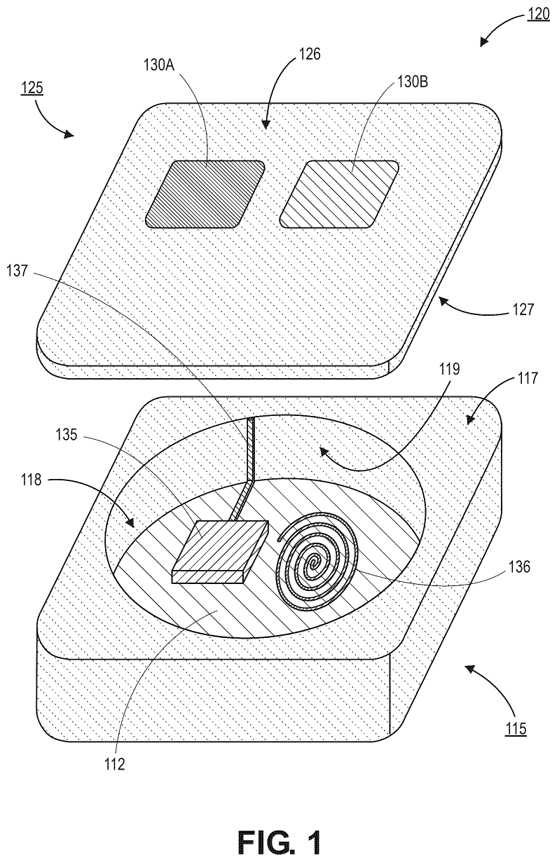

Referring now to FIG. 1, an exploded three-dimensional view of a sensor system 120 is shown, in accordance with an embodiment. In an embodiment, the sensor system 120 may comprise a housing 115. The housing 115 may have a cavity 118 formed into a top surface 117 of the housing 115. In the illustrated embodiment, the cavity 118 is circular. Though, the cavity 118 may have any desired shape. The depth of the cavity 118 may be smaller than a thickness of the housing 115. That is, the cavity 118 may not pass entirely through the housing 115 in some embodiment. In the illustrated embodiment, the bottom of the cavity 118 has a different shading. For example, a board 112 may be provided over a bottom surface of the cavity 118. In an embodiment, the board 112 may be a printed circuit board (PCB) or any other board material suitable for mounting components and providing electrical routing (e.g., a ceramic board).

In some embodiments, one or more components are provided in the cavity 118. For example, an energy storage device 135 (e.g., a battery) is provided on the board 112 within the cavity 118. An antenna 136 may also be provided on the board 112 within the cavity 118. The antenna 136 may be electrically coupled to the energy storage device 135 by electrical routing (e.g., on and/or in the board 112).

In an embodiment, the energy storage device 135 may include any suitable device that is rechargeable. For example, the energy storage device 135 may comprise a lithium-ion battery, a capacitance based energy storage device, or a device with any other suitable form of energy storage. The antenna 136 may be tuned to receive RF power provided within the chamber. For example, the RF power provided to the chamber may be suitable for initiating and/or sustaining a plasma. In some embodiments, the RF power may be around 13 MHz (e.g., approximately 13.56 MHz). In the illustrated embodiment, the antenna 136 is a spiral antenna. While a specific structure for the antenna 136 is shown in FIG. 1, it is to be appreciated that the antenna 136 may have any shape and/or design that allows for wireless coupling with an RF power source. For example, the antenna 136 may also comprise a simple trace. More generally, the antenna 136 may comprise a monopole antenna, a dipole antenna, a patch antenna, a planar inverted F-antenna, or the like.

In an embodiment, the sensor system 120 further comprises a cover 125. The cover 125 may have a first surface 126 and a second surface 127 opposite from the first surface 126. The first surface 126 may face out towards an interior volume of a plasma chamber. The second surface 127 may face towards the housing 115. The cover 125 may be secured against the housing 115 in order to seal the cavity 118. The cover 125 may be mechanically coupled to the housing 115 with any suitable structure (not shown in FIG. 1), such as clamps, clips, magnets, bolts, screws, latches, and/or the like.

In an embodiment, the cover 125 may have one or more sensors 130 provided on the first surface 126. For example, a pair of sensors 130A and 130B are shown in FIG. 1. The sensors 130A and 130B are generically shown as a block for simplicity of understanding. However, it is to be appreciated that the one or more sensors 130A and 130B may be any suitable sensor for measuring a change in thickness of a material deposited over the sensors 130A and/or 130B, monitoring material compositions of a material deposited over the sensors 130A and/or 130B, monitoring changes in material composition of a material deposited over the sensors 130A and/or 130B, and/or the like. In a particular embodiment, the one or more sensors 130A and 130B may comprise capacitance based sensors. For example, interdigitated conductive traces may be provided to provide a capacitance reading. Changes in capacitance can be correlated to changes in chamber conditions (e.g., deposition of material, changing material compositions, and/or the like). In other embodiments, impedance sensors (e.g., a surface acoustic wave (SAW) resonator or a bulk acoustic wave (BAW) resonator) may be used for the one or more sensors 130A and 130B.

In an embodiment where a pair of sensors 130A and 130B are used, differential sensing can be implemented. Differential sensing can be used to control for properties such as temperature, pressure, and/or the like. In the illustrated embodiment, the first sensor 130A may be fully exposed to the chamber environment, and the second sensor 130B may be protected from the chamber environment. For example, a protection layer or the like may be provided over the second sensor 130B.

In an embodiment, the one or more sensors 130A and 130B may be powered by the energy storage device 135 that is provided in the cavity 118. In one embodiment, the energy storage device 135 is electrically coupled to the one or more sensors 130A and 130B through one or more traces 137. For example, the trace 137 may extend from the energy storage device 135 to the sidewall 119 of the cavity 118, and the trace 137 may continue up the sidewall 119 of the cavity 118. Electrical structures (e.g., pads, bumps, vias, traces, etc.) on the cover 125 may be electrically coupled between the trace 137 and the one or more sensors 130A and 130B.

In an embodiment, the housing 115 and the cover 125 may comprise any suitable materials that can withstand the plasma processing environment. One or both of the housing 115 and the cover 125 may also be compatible with patterning processes in order to form conductive traces, vias, and/or the like. For example, electrical traces on the cover 125 may be used to form the sensors 130A and 130B, provide electrical routing between components, and/or the like. In one embodiment, the housing 115 and/or the cover 125 may comprise a ceramic material. The ceramic material may comprise aluminum oxide (e.g., Al₂O₃) in some embodiments. Though, other ceramic materials may be used in other instances.

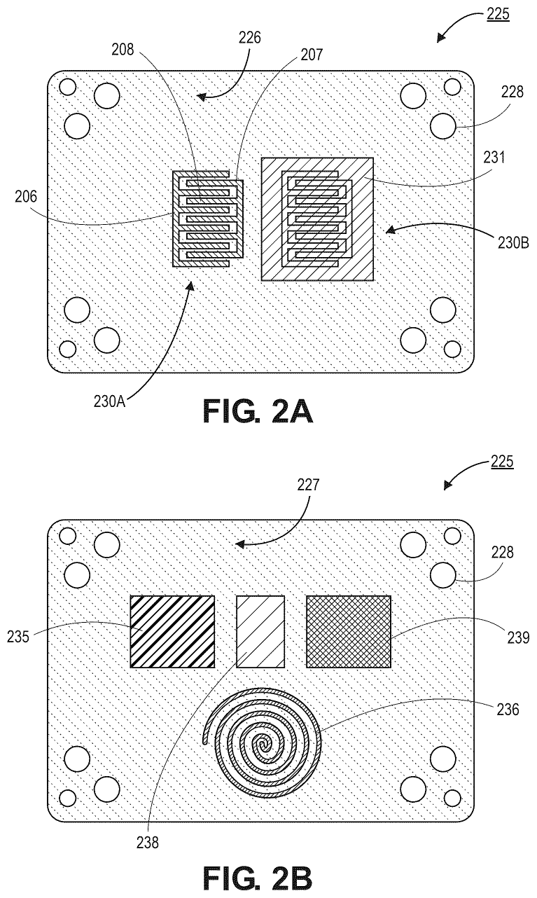

Referring now to FIGS. 2A an 2B, plan view illustrations of a cover 225 are shown, in accordance with various embodiments. FIG. 2A is a plan view illustration of the first surface 226 that faces away from the housing (not shown), and FIG. 2B is a plan view illustration of the second surface 227 that faces toward the housing (not shown).

As shown in FIG. 2A, a plan view illustration shows a first sensor 230A and a second sensor 230B. The first sensor 230A may be substantially similar to the second sensor 230B. However, the second sensor 230B may be protected or covered. For example, a layer 231 may be provided over the second sensor 230B, and the first sensor 230A is exposed. The layer 231 may be a material that is compatible with high temperature environments and/or exposure to plasma environments. In an embodiment, the layer 231 may comprise a high temperature polymer layer or an inorganic material layer.

As shown, the first sensor 230A and the second sensor 230B are capacitance based sensors. Each sensor 230A and 230B has a first electrode 206 and a second electrode 207. Both electrodes may comprise a set of interdigitated arms 208. The overlapping surface area of the arms 208 and the spacing between the arms 208 can be used to set a desired capacitance level. As material is deposited over the first sensor 230A, the capacitance between the first electrode 206 and the second electrode 207 changes. This change in capacitance can be correlated to the change in thickness of material layers provided over the first sensor 230A, a material compositions of a material deposited over the first sensor 230A, or a change in material composition of a material deposited over the first sensor 230A. In other embodiments, impedance sensors (e.g., a SAW resonator or a BAW resonator) may be used for the one or more sensors 230A and 230B.

In an embodiment, the cover 225 may also comprise holes 228. The holes 228 may be used for coupling the cover 225 to a housing (not shown). For example, screws may pass through the holes 228 and engage with threaded holes in the housing. The holes 228 may also be used for alignment purposes. In other embodiments, one or more holes 228 may be used for mounting the sensor system comprising the cover 225 to an interior surface of a chamber.

FIG. 2B provides an illustration of the second surface 227 of the cover 225. The second surface 227 may comprise one or more mounted components. Instead of providing all of the components at the bottom of the cavity of the housing (not shown), one or more of the components may be mounted to the second surface 227 of the cover 225. When the cover 225 is attached to the housing, the one or more components will extend into the cavity and be protected from the plasma environment of the chamber.

In an embodiment, the one or more components may comprise an energy storage device 235. The energy storage device 235 may be repeatedly charged by an antenna 236 that also may be provided on the second surface 227 of the cover 225. The energy storage device 235 and the antenna 236 may be similar to any energy storage device and/or antenna described in greater detail herein. The energy storage device 235 may be electrically coupled to the antenna 236 by one or more electrically conductive traces (not shown) on and/or in the cover 225. While the energy storage device 235 and the antenna 236 are shown as being on the same surface in both FIG. 1 and in FIG. 2B, it is to be appreciated that the energy storage device 235 and the antenna 236 may be provided on different surfaces within the sensor system. As will be described in greater detail herein, the antenna 236 may also be located outside of the sensor system in some embodiments.

In an embodiment, the one or more components on the second surface 227 of the cover 225 may also comprise a processor 238. The processor 238 may receive capacitance data from the one or more sensors 230A and 230B and analyze and/or store data (on an integrated memory or a discrete memory component (not shown) in the sensor system). In embodiments where data is stored on a memory, the sensor system may be periodically retrieved to extract the data from the memory to analyze chamber conditions. In other embodiments, a wireless data communication system 239 (e.g., a transceiver) may allow for wireless delivery of data to an external device outside of the chamber. This may allow for real time (or near real time) monitoring of the interior chamber conditions. The one or more additional components (e.g., the processor 238, memory (not shown), a wireless data communication system 239, an analog to digital converter, etc.) may be powered by the energy storage device 235 in some embodiments.

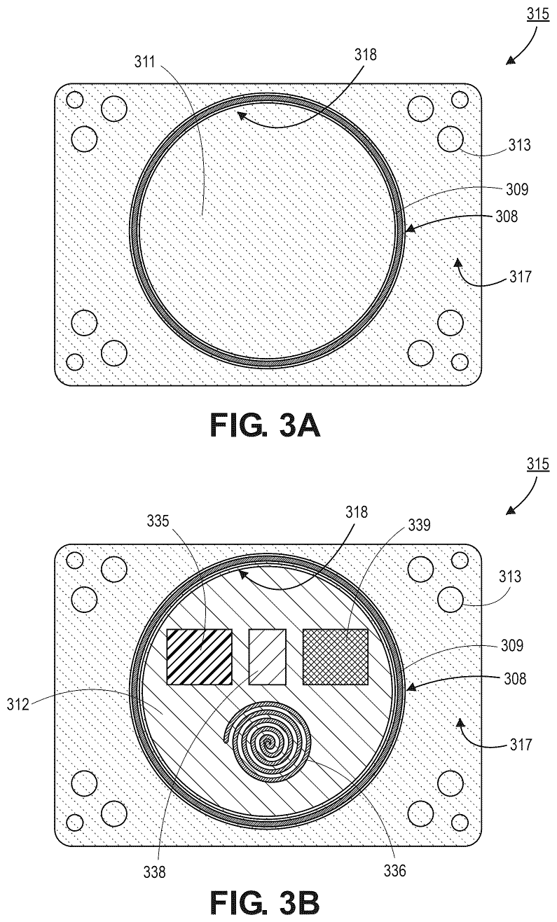

Referring now to FIGS. 3A and 3B, a pair of plan view illustrations of the housing 315 of the sensor system is shown, in accordance with an embodiment. In an embodiment, the housing 315 in FIG. 3A does not include any integrated components, and the housing 315 in FIG. 3B includes a set of integrated components provided on a board 312 at the bottom of the cavity 318.

Referring now to FIG. 3A, a plan view illustration of the housing 315 is shown, in accordance with an embodiment. As shown, a cavity 318 is formed into the top surface 317 of the housing 315. There may not be any components, boards, or other structures on a bottom surface 311 of the cavity 318. In the illustrated embodiment, the cavity 318 is circular. Though, it is to be appreciated that the cavity 318 may be any suitable shape (e.g., rectangular, square, etc.). In an embodiment, a trench 308 may be provided around a perimeter of the cavity 318. A seal ring 309 (e.g., an O-ring, a gasket, etc.) may be set into the trench 308. The seal ring 309 may be compressed by the cover (not shown) in order to provide an hermetic seal around the cavity 318.

In an embodiment, holes 313 may be provided into the top surface 317 of the housing 315. The holes 313 may be used for mechanically coupling the cover (not shown) to the housing 315. For example, one or more of the holes 313 may be threaded to receive screws that pass through corresponding holes in the cover. The holes 313 may also be used for alignment purposes or the like.

Referring now to FIG. 3B, a plan view illustration of the housing 315 with one or more integrated components is shown, in accordance with an embodiment. As shown, a board 312 is provided at a bottom of the cavity 318. The board 312 may be a PCB or the like. In an embodiment, an energy storage device 335 may be provided on the board 312. The energy storage device 335 may be charged by power received by an antenna 336 that is also provided on the board 312. The energy storage device 335 and the antenna 336 may be similar to any energy storage device and/or antenna described in greater detail herein. The antenna 336 may be electrically coupled to the energy storage device 335 through electrical traces on and/or in the board 312.

In an embodiment, additional components may also be provided on the board 312. For example, a processor 338 (which may include a memory) and a wireless data communication system 339 may be provided on the board 312 within the cavity 318. A dedicated memory component (not shown) may also be provided on the board 312 in some embodiments. Embodiments may also include an analog to digital converter on the board 312. The processor 338, the wireless data communication system 339, and/or the memory component may be similar to any of such components described in greater detail herein.

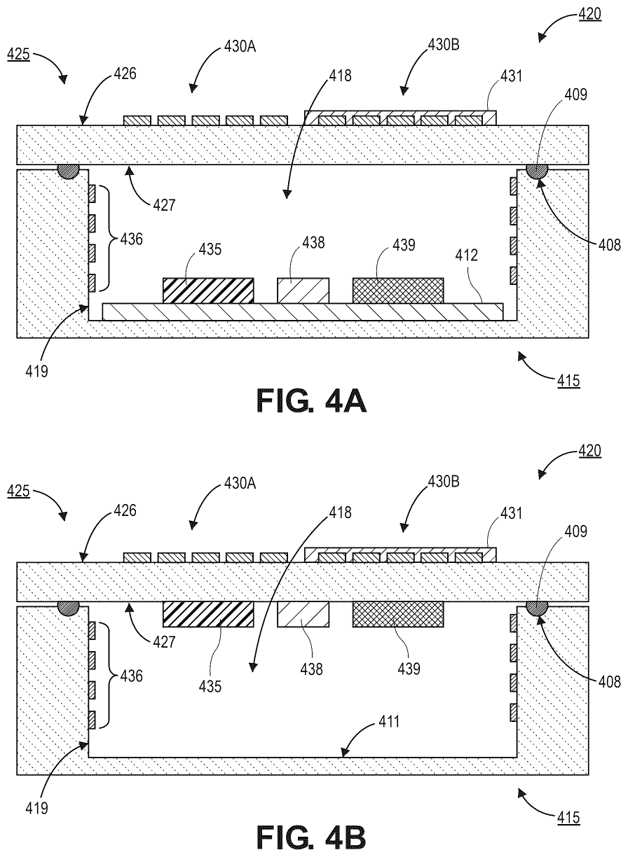

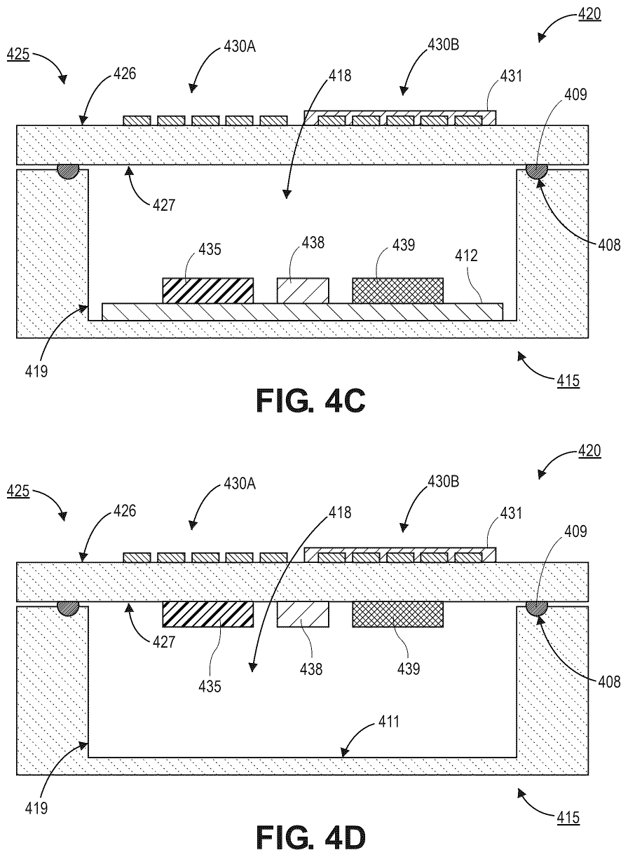

Referring now to FIGS. 4A-4D, a series of cross-sectional illustrations depicting a wireless sensor system 420 is shown, in accordance with various embodiments.

Referring now to FIG. 4A, a cross-sectional illustration of a sensor system 420 is shown, in accordance with an embodiment. As shown, a housing 415 with a cavity 418 is attached to a cover 425. For example, a bottom surface 427 of the cover 425 presses down a seal ring 409 that is set into a groove 408 in the housing 415. The seal ring 409 may provide an hermetic seal to the cavity 418 of the housing 415. In an embodiment, the housing 415 and the cover 425 may be similar to any of the housings and/or covers described in greater detail herein.

In an embodiment, a board 412 may be provided at a bottom of the cavity 418. One or more components may be coupled to the board 412. For example, an energy storage device 435, a processor 438, and a wireless data communication system 439 may be coupled to the board 412. A memory, an analog to digital converter, and/or other components may also be provided on the board 412. In an embodiment, an antenna 436 for capturing RF power from the interior of the chamber (not shown) may be provided along the sidewalls 419 of the cavity 418. For example, a coil antenna 436 may wrap around the sidewalls 419 of the cavity 418. Though, it is to be appreciated that any suitable antenna architecture may be used in some embodiments.

In an embodiment, one or more sensors 430A and 430B may be provided on a top surface 426 of the cover 425. The one or more sensors 430A and 430B may be capacitance based sensors. For example, the one or more sensors 430A and 430B may be similar to any of the sensors described in greater detail herein. In an embodiment, the first sensor 430A may be exposed to the plasma environment, and the second sensor 430B may be covered by a protective layer 431. In the illustrated embodiment, the protective layer 431 fills gaps between individual electrodes of the second sensor 430B. Though, in other embodiments, the protective layer 431 may span the gaps between electrodes without fully filling the gaps between electrodes. In other embodiments, impedance sensors (e.g., a SAW resonator or a BAW resonator) may be used for the one or more sensors 430A and 430B.

Referring now to FIG. 4B, a cross-sectional illustration of a sensor system 420 is shown, in accordance with an additional embodiment. In an embodiment, the sensor system 420 in FIG. 4B is substantially similar to the sensor system 420 in FIG. 4A, with the exception of the location of the components. Instead of being located on a board 412 at the bottom of the cavity 418, the components may be mounted to the bottom surface 427 of the cover 425, and the bottom surface 411 of the cavity 418 is uncovered. For example, one or more of the energy storage device 435, the processor 438, and the wireless data communication system 439 may be coupled to the cover 425. Despite being provided on the cover 425, the components may still be referred to as being within the cavity 418 or at least partially within the cavity 418 since they may extend at least partially below a top surface of the housing 415. In other embodiments, one or more components may be provided on the cover 425 and one or more components may be provided on a board 412 at the bottom of the cavity 418.

Referring now to FIG. 4C, a cross-sectional illustration of a sensor system 420 is shown, in accordance with an additional embodiment. In an embodiment, the sensor system 420 in FIG. 4C is substantially similar to the sensor system 420 in FIG. 4A, with the exception of the antenna 436. Instead of providing the antenna 436 for capturing the RF power within the cavity 418, the antenna is external to the sensor system 420. That is, the antenna is not visible in FIG. 4C. For example, the antenna may be located within the chamber at a location that provides more efficient coupling with the RF power. A wire or the like may be provided between the external antenna and the energy storage device 435.

Referring now to FIG. 4D, a cross-sectional illustration of a sensor system 420 is shown, in accordance with an additional embodiment. In an embodiment, the sensor system 420 in FIG. 4D may be similar to the sensor system 420 in FIG. 4B, with the exception of the antenna. Instead of providing the antenna 436 for capturing the RF power within the cavity 418, the antenna is external to the sensor system 420. That is, the antenna is not visible in FIG. 4D. For example, the antenna may be located within the chamber at a location that provides more efficient coupling with the RF power. A wire or the like may be provided between the external antenna and the energy storage device 435.

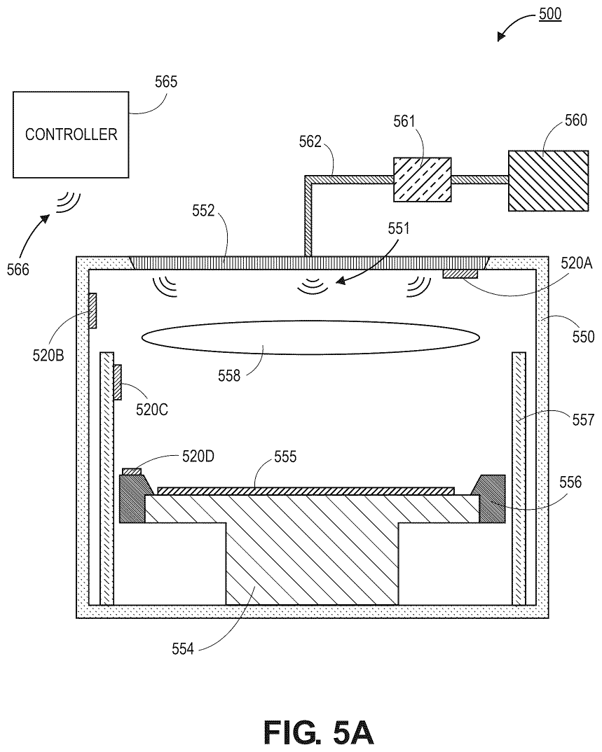

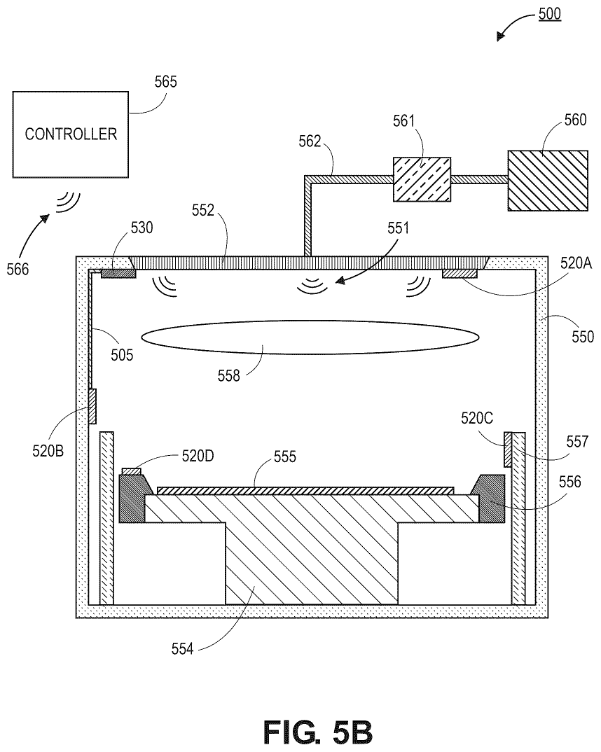

Referring now to FIG. 5A, a cross-sectional illustration of a chamber 500 is shown, in accordance with an embodiment. In an embodiment, the chamber 500 comprises a chamber wall 550. The chamber wall 550 may be sealed by a lid 552. The lid 552 may include gas distribution features (not shown), and the lid 552 may be coupled to an RF power source 560 to ignite and/or sustain a plasma within the chamber 500. For example, the RF power source 560 may be coupled to the lid 552 by an electrical connection 562 (e.g., a wire or cable) and an impedance match 561. In an embodiment, a pedestal 554 within the chamber 500 is configured to support a substrate 555. The pedestal 554 may include a chucking feature (e.g., an electrostatic chuck (ESC)) to retain the substrate 555 on the pedestal 554. The substrate 555 may be a semiconductor substrate (e.g., a silicon wafer), an organic substrate (e.g., a panel for electronic packaging fabrication), a glass panel, and/or the like.

In an embodiment, one or more sensor systems 520 may be provided along interior surfaces of the chamber 500. For example, a first sensor system 520A may be provided on the chamber lid 552, a second sensor system 520B may be provided on an interior surface of the chamber wall 550, a third sensor system 520C may be provided on a chamber liner 557, and a fourth sensor system 520D may be provided on a process kit 556 around the pedestal 554. The one or more sensor systems 520 may be similar to any of the sensor systems described in greater detail herein.

In an embodiment, the RF power 551 provided by the RF power source 560 may be used to ignite and/or sustain a plasma 558 within the chamber 500. Additionally, the RF power 551 may be used by the one or more sensor systems 520 in order to charge on board energy storage devices. For example, an antenna within each of the sensor systems 520 may pick up the RF power 551 and transmit the RF power 551 to an energy storage device on the sensor system 520. The energy storage device may then be used to power one or more sensors and/or any other components (e.g., processors, memories, wireless data communication systems, etc.) on the sensor system 520.

In an embodiment, data relating to a chamber condition detected by the one or more sensor systems 520 may be propagated from the sensor systems 520 to an external device or controller 565. For example, data 566 may be transmitted between one or more of the sensor systems 520 and the controller 565. In this way, real time (or near real time) monitoring of chamber conditions is enabled. The controller 565 may comprise circuitry for receiving and/or processing data from the sensor system 520. The controller 565 may comprise a processor, a memory, or the like. The controller 565 may be a computing device, a server, a controller, or any other suitable device for receiving and/or processing data. In some embodiments, the controller 565 may be referred to as a reader.

Stated differently, RF power 551 is delivered to the sensor systems 520, the RF power 551 is used to charge energy storage devices on the sensor systems 520, the energy storage devices power sensors within the sensor systems 520, the sensors detect the chamber condition, and the sensor system 520 delivers data related to the chamber condition to the controller 565.

Referring now to FIG. 5B, a cross-sectional illustration of a chamber 500 is shown, in accordance with an additional embodiment. The chamber 500 in FIG. 5B may be similar to the chamber 500 in FIG. 5A, with the addition of an external antenna 530 within the chamber 500. The external antenna 530 may be positioned in a location within the chamber 500 where there is a high concentration of RF power (e.g., a high magnetic field region). As such, the external antenna 530 may acquire RF power 551 more effectively than if the antenna were integrated within a sensor system 520. For example, the external antenna 530 may be electrically coupled to the second sensor system 520B by an electrically conductive wire 505 or the like. As such, the second sensor system 520B may be located at a position that would not otherwise provide good wireless power coupling. Additionally, the second sensor system 520B may not need a dedicated power coupling antenna. This can simplify the design of the second sensor system 520B.

In some embodiments, all of the sensor systems 520 within a chamber are wired to one or more external antennas 530 for power coupling. In other embodiments, one or more sensor systems 520 are coupled to external antennas 530 for power coupling, and one or more sensor systems 520 comprise integrated power coupling antennas.

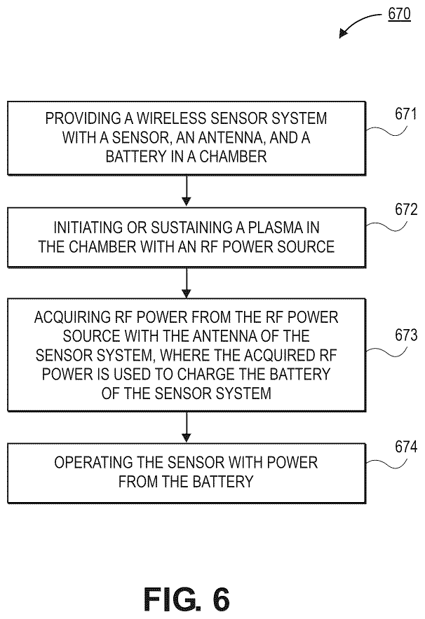

Referring now to FIG. 6, a process flow diagram of a process 670 for sensing a chamber condition with a wireless sensor system with wireless RF power charging is shown, in accordance with an embodiment. In an embodiment, the process 670 begins with operation 671 which comprises providing a wireless sensor system with a sensor, an antenna, and a battery in a chamber. In an embodiment, the wireless sensor system may be similar to any of the wireless sensor systems described in greater detail herein.

In an embodiment, the process 670 may continue with operation 672, which comprises initiating and/or sustaining a plasma in the chamber with an RF power source. In an embodiment, the RF power source may be operated at around 13 MHz. Though, any suitable frequency may be used in some embodiments. In an embodiment, the process 670 may continue with operation 673, which comprises acquiring RF power from the RF power source with the antenna of the sensor system. In an embodiment, the acquired RF power is used to charge the battery of the sensor system.

In an embodiment, the process 670 may continue with operation 674, which comprises operating the sensor with power from the battery. In an embodiment, the sensor may be a capacitive based sensor that is used to measure one or more conditions within a chamber. For example, the sensor may measure a thickness of a layer deposited on a surface of the chamber, a material composition of a layer deposited on a surface of the chamber, and/or a change in material composition of a layer deposited on a surface of the chamber. In an embodiment, the chamber condition data may be stored in a memory and/or wirelessly transmitted by the sensor system to an external controller or other computing device.

In some embodiments, the process 670 may be used in combination with machine learning (ML) or artificial intelligence (AI) systems in order to provide enhanced control of the chamber monitoring. For example, chamber condition data obtained from the sensor system can be fed into an ML and/or AI module in order to inform PM schedules. The data can be used by itself and/or in combination with historical sensor system data and/or other data sources related to the chamber, the substrates processed in the chamber, workflow through a fabrication (FAB) environment, and/or the like in order to schedule PM events in order to maximize one or more of processing uniformity, throughput, chamber utilization, chamber matching, and/or the like. The combination of chamber condition data from the sensor system and metrology data from processed substrates can also be fed into one or more ML and/or AI systems in order to optimize substrate processing uniformity, accuracy, and/or the like.

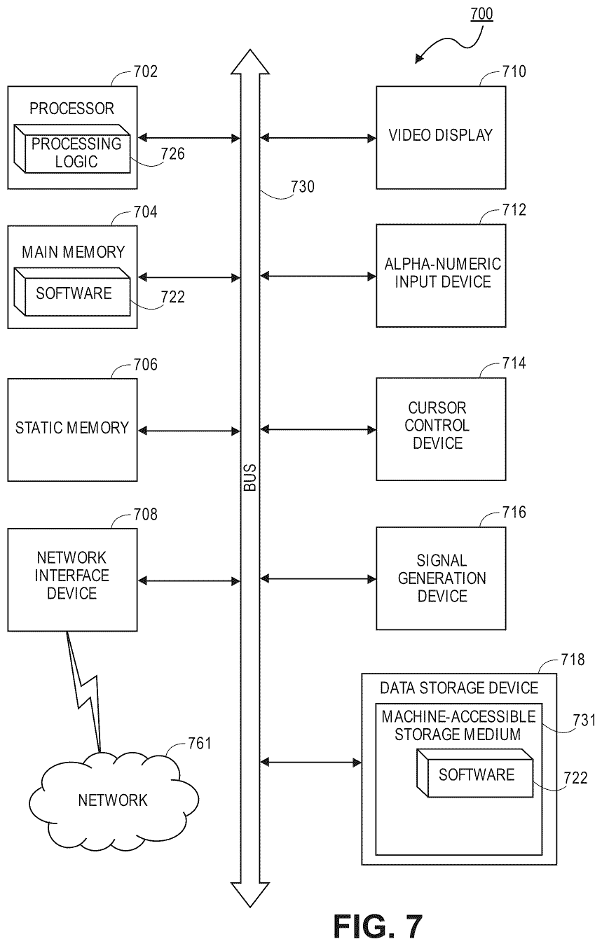

Referring now to FIG. 7, a block diagram of an exemplary computer system 700 of a processing tool is illustrated in accordance with an embodiment. In an embodiment, computer system 700 is coupled to and controls processing in the processing tool. The computer system 700 may be communicatively coupled to one or more vapor concentration sensor modules, such as those disclosed herein. The computer system 700 may utilize outputs from the one or more vapor concentration sensor modules in order to modify one or more parameters, such as, for example, processing recipe parameters, cleaning schedules for the processing tool, component replacement determinations, and the like.

Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include wireless sensors that are powered through the capture of RF power that is used to recharge a battery.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a housing with a cavity;
a cover with a first surface and a second surface, wherein the cover is coupled to the housing with the second surface facing the housing;
a sensor on the first surface of the cover; and
a battery electrically coupled to the sensor, wherein the battery is within the cavity.

2. The apparatus of claim 1, further comprising:
an antenna that is electrically coupled to the battery.

3. The apparatus of claim 2, wherein the antenna is a coil along a sidewall of the cavity, or wherein the antenna is outside of the housing.

4. The apparatus of claim 2, wherein the antenna is configured to obtain power wirelessly from a radio frequency (RF) source.

5. The apparatus of claim 1, wherein the sensor comprises:
a first sensor; and
a second sensor, wherein the second sensor is covered by a layer.

6. The apparatus of claim 1, further comprising:
a component within the cavity, wherein the component comprises a memory, a processor, an analog to digital converter, or a wireless data communication system.

7. The apparatus of claim 6, wherein the component is on a board within the cavity, or wherein the component is on the second surface of the cover.

8. The apparatus of claim 1, wherein the sensor comprises a capacitance based sensor or an impedance sensor.

9. The apparatus of claim 1, wherein the housing comprises a ceramic material.

10. The apparatus of claim 1, further comprising:
a gasket between the second surface of the cover and the housing.

11. An apparatus, comprising:
a chamber; and
a sensor system within the chamber, wherein the sensor system comprises:
a housing with a cavity, wherein the housing is coupled to an interior surface of the chamber;
a cover with a first surface and a second surface, wherein the cover is coupled to the housing with the second surface facing the housing;
a sensor on the first surface of the cover, wherein at least a portion of the sensor is exposed to an internal environment of the chamber; and
an antenna.

12. The apparatus of claim 11, wherein the antenna receives radio frequency (RF) power from RF energy used to initiate or maintain a plasma within the chamber.

13. The apparatus of claim 12, wherein the sensor system further comprises:
a battery within the cavity of the housing, and wherein the battery is charged by the RF power received by the antenna.

14. The apparatus of claim 11, wherein the sensor comprises a differential sensor with a first sensor exposed to the internal environment of the chamber and a second sensor protected from the internal environment of the chamber.

15. The apparatus of claim 11, wherein the interior surface of the chamber is a chamber wall, a chamber liner, a process kit, or a lid.

16. The apparatus of claim 11, wherein the sensor comprises a capacitance based sensor or an impedance sensor.

17. The apparatus of claim 11, wherein the sensor is configured to determine a thickness of a layer deposited over the sensor, a composition of the layer deposited over the sensor, or a change in material composition of the layer deposited over the sensor.

18. An apparatus, comprising:
a housing, wherein the housing comprises cavity, and wherein the housing is a ceramic material;
a cover coupled to the housing, wherein the cover covers the cavity in the housing;
a battery within the cavity;
an antenna electrically coupled to the battery; and
a first sensor and a second sensor on the cover facing away from the housing, wherein the second sensor is covered by a layer.

19. The apparatus of claim 18, wherein the antenna is configured to receive wireless power that is used to charge the battery.

20. The apparatus of claim 19, wherein the wireless power is obtained from RF energy used to initiate or maintain a plasma within a chamber, and wherein the apparatus is within the chamber.
